(19) United States
(12) Patent Application Publication
(10) Pub. No.: US 2025/0372354 A1
(43) Pub. Date: Dec. 4, 2025

(54) SYSTEM AND METHOD FOR PLASMA TREATMENT WITH INDEPENDENT CONTROL OF NEUTRAL PARTICLE AND ION FLUXES

(71) Applicant: Axcelis Technologies, Inc., Beverly, MA (US)

(72) Inventor: Atul Gupta, Lexington, MA (US)

(21) Appl. No.: 19/219,045

(22) Filed: May 27, 2025

Related U.S. Application Data
(60) Provisional application No. 63/652,695, filed on May 29, 2024.

(51) Int. Cl. H01J 37/32

(52) U.S. Cl. CPC H01J 37/32568; H01J 37/32752; H01J 37/32981; H01J 2237/083; H01J 2237/20228; H01J 2237/24514

(57) ABSTRACT

A plasma treatment system solves the problem of providing independent control over ion and neutral particle fluxes by separating the workpiece from the plasma and placing the workpiece on a movable stage. Extraction electrodes are used to extract ions from the plasma and beam them at the workpiece. The neutral particles are allowed to project from the plasma to the workpiece. The neutral particle flux has a much stronger dependence on distance from the plasma source than the ion flux. Accordingly, the neutral particle to ion flux ratio may be adjusted by moving the stage toward or away from the plasma source. This system has the additional advantage of enabling directional processing wherein the workpiece is held at a tilt with respect to the ion beam as the workpiece is scanned through the ion beam.

### REFERENCE TO RELATED APPLICATIONS

This application claims the benefit of U.S. Provisional Application Ser. No. 63/652,695 filed May 29, 2024, entitled, “SYSTEM AND METHOD FOR PLASMA TREATMENT HAVING INDEPENDENT CONTROL OVER NEUTRAL PARTICLE AND ION FLUX RATES”, the contents of all of which are herein incorporated by reference in their entirety.

### BACKGROUND

Plasma treatment systems are commonly used in semiconductor device manufacturing to perform etch or deposition processes on semiconductor wafers or other workpieces. In a typical system, the workpiece is placed within a plasma source so that the wafer becomes immersed in plasma. The plasma may be generated within the plasma source by means such as radio frequency, microwave, laser, or thermal activation which ionizes some of the atoms/molecules in the gas and creates the plasma. The plasma is comprised of positively and sometimes negatively charged ions, electrons, and neutral particles, among which are free radicals. As the electrons are more mobile than the ions, the interaction of this plasma with the surrounding surfaces including the walls of the plasma chamber and any substrate (e.g. a semiconductor workpiece) results in charge separation and the formation of a boundary layer called a plasma sheath near the interacting surfaces. The plasma sheath contains a strong electric field that keeps the electrons confined within the plasma and accelerates any ions that cross the sheath boundary so that they strike the surface directionally. Neutral particles, on the other hand, move from the plasma to the surface by diffusion. Combining the neutral particle flux with the energetic ion bombardment has been used in many plasma treatment applications such as plasma deposition, reactive ion etching, and other plasma based surface modifications of materials.

### BRIEF DESCRIPTION OF THE DRAWINGS

FIGS. 1A-1C illustrates a plasma treatment system in accordance with some aspects of the present disclosure.

FIGS. 2A-2C illustrates the plasma treatment system of FIGS. 1A-1C in operation.

FIG. 3 illustrates a plasma treatment system in accordance with an embodiment.

FIG. 4 illustrates a plasma treatment system in accordance with another embodiment.

FIG. 5 provides a flow chart for a method in accordance with some aspects of the present disclosure.

FIGS. 6A-6C illustrate a workpiece under treatment according to a process of the present disclosure.

FIG. 7 provides a flow chart for another method of the present disclosure.

### DETAILED DESCRIPTION

The present disclosure provides many different embodiments, or examples, for

implementing different features of the invention. Specific components and arrangements are provided to clarify and exemplify the invention. These specific examples should not be interpreted as limiting the scope of what is claimed.

A key challenge with plasma treatment systems arises from the need for independent control over neutral particle and ion fluxes. For many etch and deposition processes a balance between neutral particle flux (flow rate per unit area), especially free radical flux, and ion flux is crucial. For example, some reactive ion etching processes used to form high aspect ratio trenches need to balance the rate of a primarily ion-driven process of etching at the bottoms of the deepening trenches with the rate of a primarily free radical-driven process by which a protective polymer coating forms on the sidewalls of the trenches. The balance between free radicals and ions may be controlled by adjusting parameters such as gas composition, pressure, plasma power, and electrode configuration. But these parameters affect the conditions of the plasma which makes this type of control difficult or even unstable due to the complexity of the ultimate relationship between the parameters under adjustment and the ion and free radical fluxes over which control is sought.

Some aspects of the present invention relate to a system that simplifies control over the ratio between ion and neutral particle fluxes as well as control over the direction and energy of ions interacting with the substrate. In this system, the wafer or other workpiece is placed in a process chamber outside the plasma source. The plasma source is coupled to the process chamber. Ions are extracted through an aperture in the plasma chamber walls and accelerated into a beam that is directed at the workpiece. The system is configured to allow neutral particles in the plasma to project through the aperture along the ion beam's path. The neutral particle flux in the ion beam varies approximately in proportion to the inverse square of the distance. The ion flux has a much weaker dependence on the distance. Accordingly, the ratio between ion and neutral particle fluxes may be controlled by varying the distance between the workpiece and the plasma source. In some embodiments, the workpiece is mounted on a workpiece support that may be electronically controlled to vary a distance between the workpiece and the plasma source.

In some embodiments, the process chamber includes a sensor that can be used to measure neutral particle or free radical flux. In some embodiments, the sensor is mounted to the workpiece support. In some embodiments, the sensor is positioned to measure the neutral particle or free radical flux during over scan of a wafer mounted to the workpiece support. In some embodiments, a controller is programmed with a feedback control loop that varies the distance along the ion beam at which the workpiece support holds a workpiece based on data from the sensor.

In some embodiments, the ions are extracted using a set of extraction electrodes positioned outside the aperture. The ions are extracted by driving a potential difference between the plasma chamber walls and the set of extraction electrodes. Using a set of extraction electrodes to extract the ions makes the ion flux more weakly dependent on the distance between the workpiece and the plasma source compared to the case where the ions are extracted by driving a potential difference between the plasma chamber walls and the workpiece. Moreover, the ion extraction rate is made almost entirely independent on the distance between the plasma chamber and the workpiece, which improves control over the plasma when that distance is made variable. In some embodiments, the workpiece is grounded. Grounding the workpiece avoids plasma discharge effects.

A potential difference between the plasma chamber and the set of extraction electrodes determines the energy of the extracted ions. The potential difference may be applied in a duty cycle so that the energy of the ions and their extraction rate may be independently controlled. In some embodiments, during an active period of the duty cycle, the plasma chamber is held at a potential above ground and the set of extraction electrodes are grounded. Placing the positive potential on the plasma chamber enables the substrate and process chambers to be held at ground potential while allowing improved extraction efficiency of the beam. Pulsed extraction can be used to control the ratio of the total radical flux to total energetic ion flux. However, that approach can impact the average electron and ion density in the plasma and thus present process control challenges.

In some embodiments, a set of suppression electrodes are disposed between the plasma chamber and the set of extraction electrodes. During the active period of the duty cycle, the set of suppression electrodes are held at a potential below that of the set of extraction electrodes. The set of suppression electrodes may prevent electrons from arcing from the set of extraction electrodes to the plasma chamber. In some embodiments, for the inactive period of the duty cycle the set of suppression electrodes are brought to the same potential as the plasma chamber, which may be ground. This process prevents the set of suppression electrodes from extracting ions from the plasma chamber during the inactive period of the duty cycle.

In some embodiments, the aperture has the form of a slit and the extracted ions are formed into a beam having an oblong shape, such as a ribbon or other form where the width is much greater than the height. In some other embodiments, the aperture is shaped so that the extracted ions are formed into a beam having a more two-dimensional shape such as circular, elliptical, rectangular, or the like. Ion beams having relatively two-dimensional shapes can be easier to control than ion beams having oblong shapes. In some embodiments, there are a plurality of apertures. A plurality of apertures may be used to form a plurality of beams, or the beams from the various apertures may be allowed to merge into one beam. Having multiple apertures for extracting ions reduces conductance and enables better prevention of interactions between the plasma and upstream flowing secondary electrons of the type produced by interactions with the ion beam.

In some embodiments, a workpiece handler is configured to translate the workpiece so that the ion beam scans across a workpiece surface. The distance between the plasma chamber and the workpiece may be held constant as the workpiece surface is scanned. Moving the workpiece rather than steering the ion beam allows the workpiece to be scanned without deflecting the ion beam. Steering the ion beam presents challenges for reactive ion etching and similar processes due to the charge-to-mass ratio varying among the ions in the ion beam. In some embodiments, the ions are accelerated along a direct line-of-sight from the plasma chamber to the workpiece through the aperture.

The foregoing system enables applications beyond those possible using a conventional plasma treatment system. In particular, the system may be used for directional etching in which the workpiece is held at a tilt with respect to the ion beam. In some embodiments, the workpiece handler is configured to scan the workpiece through the ion beam while maintaining the workpiece surface at a predetermined tilt with respect to the ion beam. The tilt may be in a direction that keeps the workpiece surface parallel to a width of the beam so that a distance between the workpiece surface and the plasma chamber does not vary significantly from one side of the beam to the other. Moreover, in some embodiments the workpiece handler is configured to scan the workpiece surface through the ion beam while maintaining the workpiece surface in a fixed process plane so that neither the ion beam distance to the workpiece surface being treated nor the ion beam's angle of incidence on the workpiece varies during the scan. In some embodiments, the workpiece handler comprises a three-jointed robot. In some embodiments, the robot is a Selective Compliance Articulated Robot Arm (SCARA), which is a type of robot having compliance in an X-axis and a Y-axis, and rigidity in a Z-axis.

In some embodiments the workpiece is processed in two or more steps wherein the ion beam condition (ion energy or density), the workpiece orientations, or the process plane is varied between the steps. Varying the process plane may include changing the angle of tilt or changing the distance of the process plane from the plasma source. In some embodiments, the process plane is maintained, but the workpiece is rotated between scans to direct the ion beam at two sides of a feature on the surface of the workpiece (e.g. opposing sides of a trench may be treated by rotating the workpiece 180 degrees between scans).

The present disclosure enables applications in which a workpiece is treated in two or more stages without removing the workpiece from the process chamber and in which a ratio between ion and neutral particle fluxes varies between stages. In the first stage, the workpiece may be scanned while held at a first distance from the plasma source. In the second stage, the workpiece may be scanned while held at a second distance from the plasma source. This process can be used, for example, to vary the ion to neutral particle ratio as trenches are made progressively deeper in a reactive ion etching process.

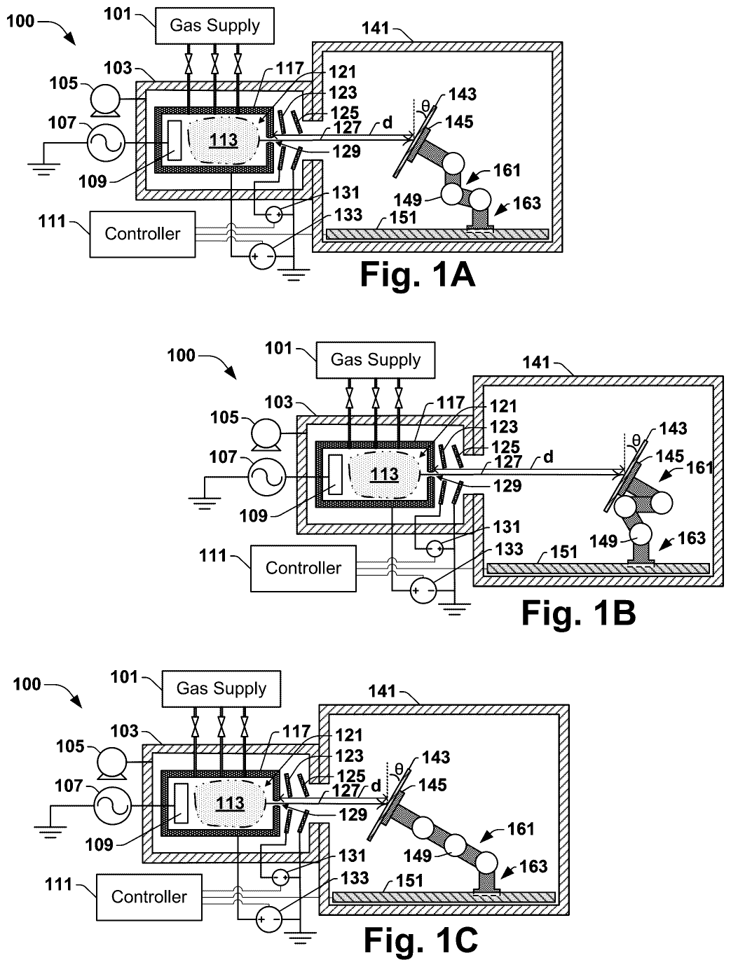

FIGS. 1A-1C illustrates a plasma treatment system 100 in accordance with some embodiments of the present invention. The plasma treatment system 100 includes a plasma source 103, a process chamber 141, a vacuum pump 105, and a high voltage power supply 107. The plasma source 103 includes plasma chamber walls 117 surrounding a plasma chamber 121. The plasma source 103 is coupled to the process chamber 141, and the plasma chamber 121 is in fluid communication with the process chamber 141 through an aperture 129 in the plasma chamber walls 117. The vacuum pump 105 is operative to draw a vacuum on both the plasma chamber 121 and the process chamber 141.

The plasma source 103 may include a filament or cathode 109 that is capacitively or inductively coupled to the high voltage power supply 107. The filament or cathode 109 produces electrons which may be induced to arc and ionize reagents from the gas supply system 101 within the plasma chamber 121 and generate a plasma 113. The high voltage power supply 107 may operate at radio frequency. In some embodiments, the high voltage power supply 107 operates at microwave frequency, which facilitates providing the plasma 113 with high density. A high plasma density helps achieve satisfactory etch and deposition rates when the workpiece 143 is displaced from the plasma 113 by enabling higher densities of neutral particles and ions in an ion beam extracted from the plasma source 103. A magnetic field may be provided to create a higher plasma density by confining the electron motion within the plasma 113 in a swirling pattern, however, in some embodiments the plasma source 103 is of the type that does not include magnetic confinement.

There is a line of sight along a beam path 127 from the plasma chamber 121 into the process chamber 141 through aperture 129. The aperture 129 may be a slit. A set of extraction electrodes 125 is disposed in front of the aperture 129. The set of extraction electrodes 125 comprises one or more electrodes flanking or surrounding the beam path 127. For example, the set of extraction electrodes 125 may comprise two electrode plates on opposite sides of the beam path 127 or a single rectangular electrode surrounding the beam path 127. The set of electrodes may be or comprise perforated plates, grids, arrays of plates, combinations thereof, or any other suitable electrode structure. In some embodiments, the extraction electrodes 125 are arranged symmetrically with respect to the aperture 129. Symmetrical arrangement avoid steering of ions that can result in non-uniform treatment of a workpiece. In some embodiments, the extraction electrodes 125 are mounted at fixed locations relative to the aperture 129. Keeping the extraction electrodes 125 at fixed locations relative to the aperture 129 improves control and reproducibility of plasma treatment processes according to the present disclosure.

A DC power source 133 has an anode connected to the plasma chamber walls 117 and a cathode connected to the set of extraction electrodes 125. The cathode of the DC power source 133 may also be connected to ground. In some embodiments, the DC power source 133 is operative to produce a voltage in the range from about 100 V to about 30 kV for drawing positive ions from the plasma 113 through the aperture 129 and accelerating them along the beam path 127. In some embodiments, the DC power source 133 is operative to produce a voltage in the range from about 300 V to about 2 kV. The energy of the ions may be selected based on the desired penetration depth into a workpiece under treatment.

A set of suppression electrodes 123 may be disposed at an intermediate distance between the plasma chamber walls 117 and the set of extraction electrodes 125. The set of suppression electrodes 123 comprises one or more electrodes flanking or surrounding the beam path 127. For example, the set of suppression electrodes 123 may comprise two electrode plates on opposite sides of the beam path 127 or a single rectangular electrode surrounding the beam path 127. A DC power source 131 has a cathode connected to the set of suppression electrodes 123 and or to ground. In some embodiments, the DC power source 131 is operative to produce a voltage in the range from about −100 V to about −2 kV. Ions striking the extraction electrodes 125 may produce electrons. The suppression electrodes 123 prevent those electrons from arcing into the plasma 113. The suppression electrodes 123 also prevent electrons in the ion beam from being drawn back into the plasma 113, and thus prevent the type of beam blowup that can occur when positively charged ions in the ion beam are not balanced with neutralizing electrons.

A workpiece support 163 mounted in the process chamber 141 has a chuck 145 for holding a workpiece 143. The chuck 145 may be a mechanical chuck, an electrostatic chuck, a vacuum chuck, or some other type of chuck suitable for holding a workpiece 143 or some other type of workpiece. The workpiece support 163 may include a workpiece handler 161 and a stage 151. The workpiece handler 161 may be or comprise a three-jointed robotic arm such as a SCARA. As shown in FIGS. 1B and 1C, the workpiece support 163 is operative to hold the workpiece 143 at a variable distance d along the beam path 127. The distance d may be varied by articulating the joints 149 of the workpiece handler 161. Alternatively, or in addition, the distance d may be varied by translating the workpiece handler 161 along the stage 151.

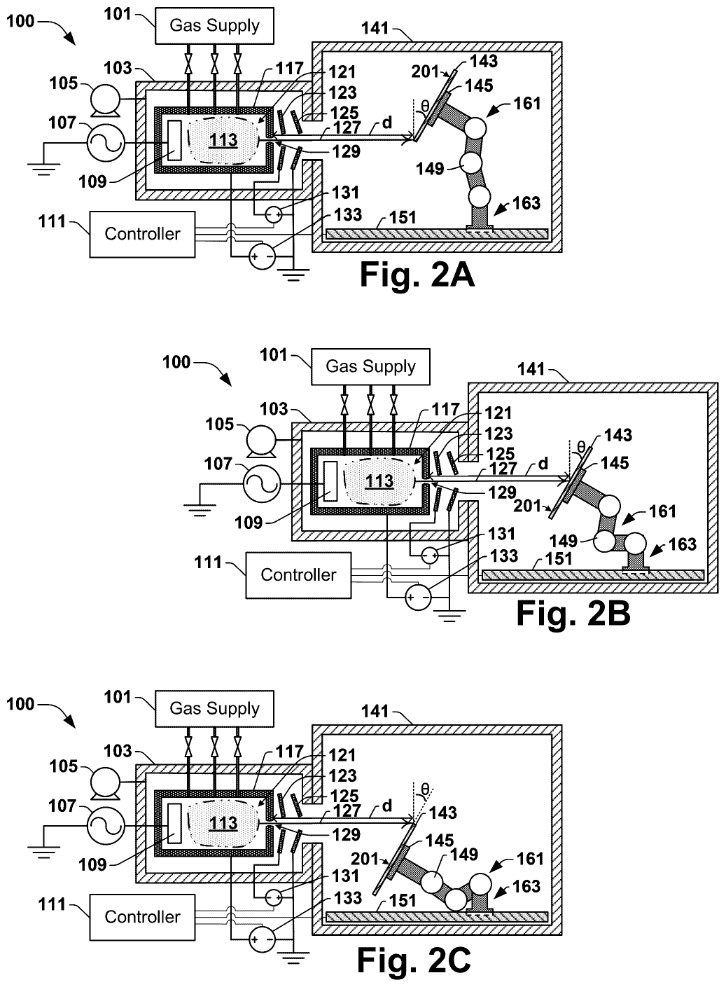

As shown by FIGS. 2A-2C, the workpiece handler 161 is operative to scan the workpiece 143 through the beam path 127 while maintaining the workpiece 143 in a process plane. Maintaining the workpiece 143 in a process plane includes keeping the distance d of the workpiece 143 along the beam path 127 constant and maintaining a workpiece surface 201 at a constant angle of inclination θ with respect to the beam path 127. In some embodiment, the angle of inclination θ is non-zero, so that the process plane is tilted with respect to the beam path 127.

Scanning the workpiece 143 through the beam path 127 while keeping the distance d and the angle of inclination 0 constant makes the conditions of treatment the same for every location on the workpiece surface. This improves process control by minimizing variations in plasma treatment received at different locations on the workpiece surface. Such tight process control is not possible if a titled workpiece is translated in a fixed direction perpendicular to the beam path 127 since the top and bottom portions of the workpiece would be treated while at different distances along the beam path 127.

A controller 111 may be configured to operate the workpiece support 163, the DC power source 133, the DC power source 131, and or the various controls of the plasma source 103. In particular, the controller 111 may be operative to send instructions to the workpiece support 163 and to pulse the DC power source 133 in a duty cycle having active periods and inactive periods. In some embodiments, the controller 111 provides the same duty cycle to the DC power source 131 so that the set of suppression electrodes 123 are at a negative voltage during only the active period of the duty cycle. The controller 111 is an electronic control system, which is a control system comprising a processor and memory programed with instructions for carrying out the recited functions.

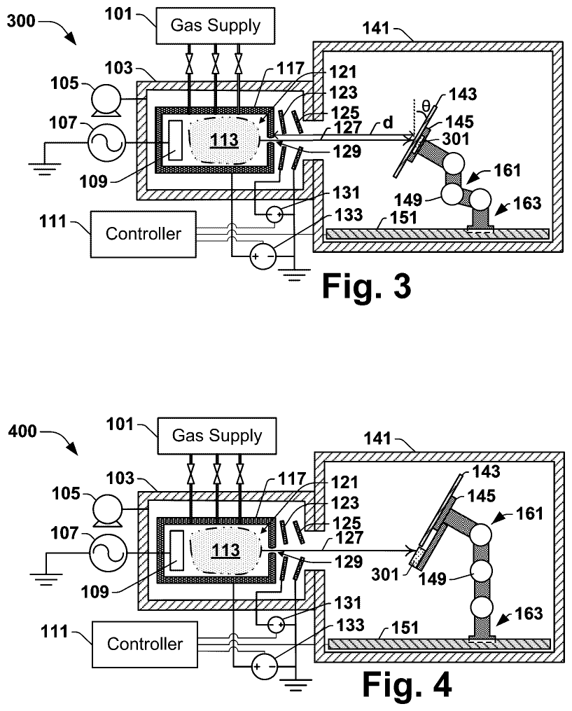

FIG. 3 illustrates a plasma treatment system 300. The plasma treatment system 300 is like the plasma treatment system 100 of FIG. 1A except that the plasma treatment system 300 includes a sensor 301 that has an output responsive to variations in neutral particle flux. A Faraday cup or other sensor operative to measure the ion flux may also be provided. Free radical flux varies proportionally with neutral particle flux with respect to the distance d. Therefore, a measurement of neutral particle flux may be used as a proxy for a measurement of free radical flux, or a measurement of free radical flux may be used as a proxy for a measurement of neutral particle flux.

The sensor 301 may be a photodetector that detects optical emissions produced by free radicals, a calorimeter that measures heat produced by free radical reactions, an electrochemical sensor that detects free radicals based on redox reactions, a quartz crystal microbalance, the like, or any other type of sensor that produces an output responsive to variations in free radical flux. A photodetector may be used in combination with a fluorescent compound, a chemiluminescent compound, a quartz crystal, or the like. In some embodiments, the sensor 301 is in the chuck 145 or is otherwise mounted to the workpiece support 163 in such a way that the sensor 301 is blocked from the beam path 127 when a workpiece 143 is mounted on the workpiece handler 161. Data from the sensor 301 may be used to adjust the distance d before treatment of the workpiece 143.

FIG. 4 illustrates a plasma treatment system 400. The plasma treatment system 400 is like the plasma treatment system 300 of FIG. 3 except that the in the plasma treatment system 400 the sensor 301 is positioned to be in the beam path 127 during over scan of the workpiece 143. The sensor 301 may be mounted to the workpiece support 163 so that the sensor 301 is approximately the distance d from the plasma chamber 121 when the sensor 301 enters the beam path 127.

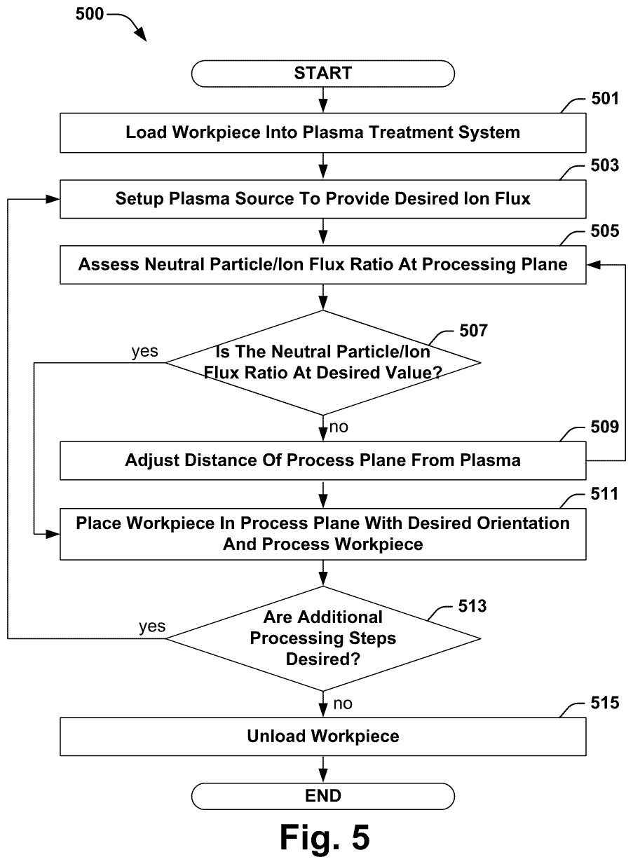

FIG. 5 provides a flow chart of a method 500 according to some embodiments of the present invention. While the method 500 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein.

The method 500 may begin with act 501, loading a workpiece into the process chamber of a plasma treatment system. After loading the workpiece, the process chamber is placed under vacuum.

Act 503 is setting up the plasma source to form a plasma and extract an ion beam having a desired ion flux. The plasma source can be set up in accordance with a recipe that includes specifications for the reagent gas compositions and flow rates, the pressure, and other parameters that determine the composition of the plasma. The reagents are selected in accordance with the type of process being carried out. The process may be, for example, a reactive ion etch process, a plasma enhanced chemical vapor deposition process, or the like. In some embodiments, the reagents include a fluorocarbon compound (e.g., CₓF_{y}), which may provide a source for fluorocarbon polymer precursors. In some embodiments, the reagents include a chemical etchant source such as oxygen (O₂) or another oxygen-containing compound. In some embodiments, the reagents include an inert species ion source such as helium (He), neon (Ne), argon (Ar), or the like. In some embodiments, the reagents include a combination of a fluorocarbon compound, an oxygen-containing compound, and an inert species.

Setting up the plasma source to extract an ion beam having the desired ion flux may include operating a power source connected between the plasma chamber walls and a set of extraction electrodes according to a duty cycle. The workpiece may be used as the set of extraction electrodes, but that approach has the disadvantage of making the extraction rate dependent on the distance d between the plasma chamber and the workpiece. Accordingly, in some embodiments the set of extraction electrode is at a distance intermediate between the workpiece and the plasma chamber. The voltage for the active periods of the duty cycle may be selected according to a desired energy for the ions. The ratio between the active and inactive periods of the duty cycle may be selected according to a target ion flux. Generating the ion beam naturally results in a neutral particle flux at the process plane when using a plasma treatment system according to the present disclosure. The ion flux in the ion beam may be measured and adjusted if necessary before proceeding to the next step.

Act 505 is assessing a neutral particle-to-ion flux ratio in the ion beam at a processing plane. The process plane has a specified distance d (see FIG. 1A) from the plasma chamber along the beam path and may have a specified angle of inclination θ with respect to the beam path. An initial value for the distance d at which a desired ion-to-neutral particle flux ratio will be achieved may be estimated. The neutral particle-to-ion flux ratio can be a ratio between the fluxes of all types of neutral particles and ions, a ratio between fluxes of free radicals and ions, or the like. The assessment may comprise a measurement of the neutral particle flux, the free radical flux, a film growth rate, or some other property that varies in relation to a neutral particle-to-ion flux ratio.

Act 507 is determining whether the neutral particle-to-ion flux ratio as determined by the assessment is at a predefined target ratio. The predefined target ratio does not need to be made explicit, but is defined sufficiently to make a determination as to whether the neutral particle-to-ion flux ratio is above or below the predefined target based on the assessment of act 505. For example, calibration may be used to relate a measurement made in the previous step to whether the assessed neutral particle-to-ion flux ratio is above, below, or at the predefined target ratio.

If the assessed neutral particle-to-ion flux ratio is not at the predefined target ratio, the method 500 continues with act 509, which is adjusting the distance d (moving the process plane). The neutral particle flux at the workpiece surface is proportional to the neutral particle density in the plasma and approximately inversely proportional to the distance d. The ion flux, on the other hand, has a much weaker dependence on d in a relationship that has dependencies on the energies of the ions, the shape of the plasma chamber aperture, and the geometry of the extraction electrodes. Accordingly, the distance d is increased if the assessed neutral particle-to-ion flux ratio is above the predefined target ratio and the distance d is reduced if the assessed neutral particle-to-ion flux ratio is below the predefined target ratio. After adjusting the distance d, the method may return to act 505 and repeat the assessment of the neutral particle-to-ion flux ratio.

When the assessed neutral particle-to-ion flux ratio is satisfactorily close to the predefined target ratio, the method 500 may proceed with act 511, placing the workpiece (more precisely, a surface thereof) in the process plane and processing the workpiece while maintaining the workpiece in the process plane. In some embodiments, the orientation of the workpiece within the process plane (angle of rotation) is significant, and placing the workpiece is set to the desired orientation. Processing the workpiece includes moving the workpiece so that the ion beam scan the workpiece surface. In some embodiments, the ion beam is oblong having a width greater than or equal to that of the workpiece so that a single scan in one direction treats an entire face of the workpiece. In some embodiments, the workpiece is scanned in two directions, an x-direction and a y-direction. The scan rate and the number of scans may be selected to provide a desired amount of treatment.

Once the current workpiece processing operation is complete, the method 500 proceeds to decision block 513 where it is determined whether one or more additional workpiece processing operations are to be performed by the plasma treatment system. If not, the workpiece is unloaded with act 515. However, loading and unloading are time consuming operations that reduce productivity and an ion implantation system according to the present disclosure lends itself to many different types of processes. Accordingly, at method 500 may return to act 503 to begin an additional workpiece processing operation.

In some embodiments, the additional processing operation involves a difference in the plasma source setup. The plasma source may be setup to provide a different gas composition, a different ion flux rate, or the like. In some embodiments, the additional workpiece processing operation involves the same plasma source set-up as the first previous workpiece processing operation, but uses a different neutral/particle to ion flux ratio, which may be achieved by moving the process plane to a new distance d from the plasma source. In some embodiments, the additional workpiece processing includes changing the angle of inclination 0 of the process plane. In some embodiments, the additional workpiece processing operation involves rotating the workpiece while maintaining the same plasma source setup and processing plane as used in the previous workpiece processing operation. Combinations of the foregoing are also possible.

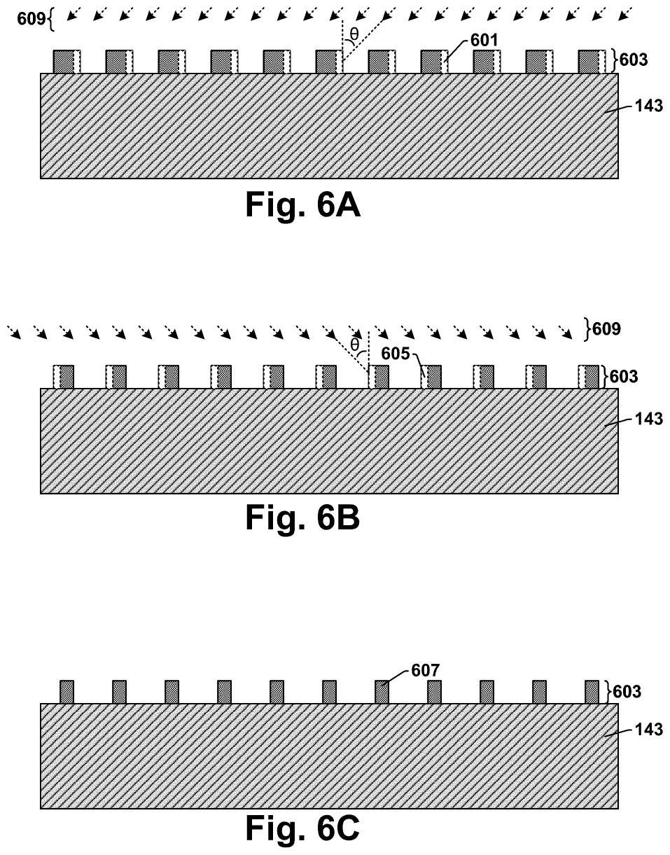

One example of an additional workpiece processing operation is rotating the workpiece 180 degrees while maintaining the workpiece in the same process plane, and again scanning the workpiece through the ion beam. This additional workpiece treatment operation can symmetrically treat opposite sidewalls of the workpiece. FIGS. 6A-C provide an example in which two plasma treatment operations are used for mask trimming. As shown in FIG. 6A, a first scan of an ion beam 609 striking the workpiece at the angle of inclination 0 may be used to trim right side portions 601 of a mask 603. As shown in FIG. 6B, a second scan may be used to trim left side portions 605 of the mask 603. As shown in FIG. 6C, the effect may be to narrow the features 607 of the mask 603.

In some embodiments, first and second workpiece processing operations are repeated cyclically. Alternating between two or more conditions can be useful in a variety of processes. One example is a process of etching high aspect ratio trenches in which periods of forming a passivating polymer layer on the trench sidewalls are alternated with periods of deepening the trenches.

Conducting multiple scans with the angle of incidence of the ion beam on the workpiece surface varying between the scans encompasses another family of processes enabled by some embodiments of the present invention. For example, replacing one etch at one angle of incidence with two shorter etches at different angles of incidents adds an additional degree of freedom that allows more precise shaping of features on the workpiece surface.

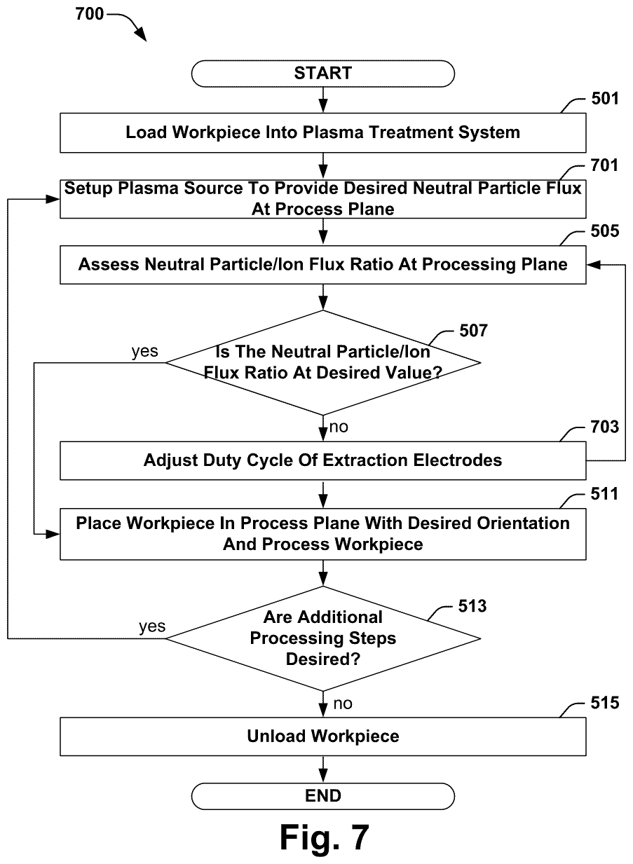

FIG. 7 provides a flow chart of a method 700. The method 700 is similar to method 500 of FIG. 5 but differs in act 701, which relates to the initial setup of the plasma source and the processing plane, and act 703 which relates to how the neutral particle-to-ion flux ratio is adjusted, if needed. In act 701 the plasma source is setup and/or the process plane is adjusted to provide a desired neutral particle flux at the process plane. In act 703 the duty cycle of the extraction electrodes is adjusted to change the ion flux rate without affecting the neutral particle flux rate. The methods 500 and 700 together illustrate that an ion treatment system of the present disclosure provide two ways to adjust the neutral particle-to-ion flux ratio: adjust the distance of the implant place from the plasma source, or adjust the duty cycle of the extraction electrode. Both types of adjustment may be used to independently adjust a neutral particle flux rate and an ion flux rate without changing the conditions of plasma formation.

Some aspects of the present disclosure relate to a plasma treatment system that includes a process chamber and a plasma source mounted to the process chamber. The plasma source comprises a plasma chamber having walls. An aperture is formed through the walls. A DC power source is connected between the walls and one or more second electrodes outside the plasma chamber. The one or more second electrodes are positioned to draw ions from the plasma chamber through the aperture and accelerate them into the process chamber along a trajectory. The trajectory corresponds to a line of sight from the plasma chamber to the process chamber through the aperture. There is a workpiece handler within the process chamber. The workpiece handler is operable to vary a distance of a workpiece from the plasma chamber.

Some aspects of the present disclosure relate to a method of operating a plasma treatment system. The method includes placing a workpiece on a workpiece handler in a process chamber, generating a plasma in a plasma chamber, extracting ions from the plasma chamber through the aperture and accelerating the ions along a line of sight toward the workpiece, and adjusting a distance from the plasma chamber at which the workpiece handler holds the workpiece according to a determination to either increase or decrease a free radical flux to ion flux ratio at a surface of the workpiece.

Some aspects of the present disclosure relate to a plasma treatment system that includes a process chamber and a plasma source mounted to the process chamber. The plasma source comprises plasma chamber walls, and an aperture is formed through the plasma chamber walls. A DC power source is connected between the plasma chamber walls and one or more second electrodes outside the plasma chamber walls, wherein the one or more second electrodes are positioned to draw ions from the plasma chamber through the aperture and accelerate them along a trajectory into the process chamber. The trajectory corresponds to a line of sight from the plasma chamber to the process chamber through the aperture. A workpiece handler is mounted within the process chamber. The workpiece handler is operable to scan a workpiece through a point along the trajectory while maintaining a planar surface of the workpiece in a plane having a normal vector that is tilted relative to the trajectory.

In some embodiments, the workpiece handler is operable to vary a distance of the point along the trajectory. In some embodiments, the one or more second electrodes are a set of extraction electrodes located between the workpiece handler and the plasma chamber. In some embodiments, the workpiece handler comprises a three-jointed robotic arm. In some embodiments, there is a set of suppression electrodes between the set of extraction electrodes and the plasma chamber. In some embodiments, the plasma chamber is isolated from ground and the DC power source is configured to raise the plasma chamber to a potential above ground.

Some aspects of the present disclosure relate to a method that include placing a workpiece in a process chamber, generating a plasma in a plasma chamber, wherein the plasma chamber has an aperture through which there is a line of sight to the workpiece, extracting ions from the plasma chamber through the aperture and accelerating the ions along the line of sight toward the workpiece so as to form a first ion beam, and while maintain the workpiece at a first tilt with respect to the line of sight, translating the workpiece so that the first ion beam scans across a surface of the workpiece to complete a first scan.

In some embodiments, the method further includes extracting ions from the plasma chamber through the aperture and accelerating the ions along the line of sight toward the workpiece so as to form a second ion beam, and, while maintain the workpiece at a second tilt with respect to the line of sight, translating the workpiece so that the second ion beam scans across the surface of the workpiece, wherein the second tilt is distinct from the first tilt. In some embodiments, the method further includes, after the first scan, changing a distance between the workpiece and the plasma chamber, extracting ions from the plasma chamber through the aperture and accelerating the ions along the line of sight toward the workpiece so as to form a second ion beam, and while maintain the workpiece at a second tilt with respect to the line of sight, translating the workpiece so that the second ion beam scans across a surface of the workpiece to complete a second scan. In some embodiments, the method further includes extracting ions from the plasma chamber through the aperture and accelerating the ions along the line of sight toward the workpiece under a changed extraction condition so as to form a second ion beam, wherein the changed extraction condition alters an energy of the ions or a rate of ion extraction, and while maintain the workpiece at a second tilt with respect to the line of sight, which may be the same as or different from the first tilt, translating the workpiece so that the second ion beam scans across the surface of the workpiece.

Some aspects of the present disclosure relate to a plasma treatment system that includes a process chamber a plasma source mounted to the process chamber, wherein the plasma source comprises a plasma chamber, and an aperture is formed through a wall of the plasma chamber, and one or more extraction electrodes outside the plasma chamber, wherein the one or more extraction electrodes are positioned to draw ions from the plasma chamber through the aperture and accelerate them along a trajectory into the process chamber, and the trajectory corresponds to a line of sight from the plasma chamber to the process chamber through the aperture.

Some aspects of the present disclosure relate to a method that includes placing a workpiece in a process chamber, generating a plasma in a plasma chamber, wherein the plasma chamber has an aperture through which there is a line of sight to the workpiece, using a set of extraction electrodes to extract ions from the plasma chamber through the aperture and to accelerate the ions along the line of sight toward the workpiece, wherein the set of extraction electrodes are located between the workpiece and the plasma chamber, and translating the workpiece so that the ions are scanned across a surface of the workpiece.

In some embodiments, using a set of extraction electrodes to extract ions from the plasma chamber through the aperture and accelerate the ions along the line of sight toward the workpiece comprises pulsing a DC voltage difference between the plasma chamber and the set of extraction electrodes. In some embodiments, the process chamber is isolated from ground and pulsing a DC voltage difference between the plasma chamber and the set of extraction electrodes comprises raising the process chamber to a potential above ground during an active period of a duty cycle. In some embodiments, the method further includes holding a set of suppression electrode at a potential below ground during the active period of the duty cycle, wherein the suppression electrodes are closer to the plasma chamber than the set of extraction electrodes.

The foregoing outlines features of several embodiments so that those skilled in the art may better understand the aspects of the present invention. Those skilled in the art should appreciate that they may readily use the present invention as a basis for designing or modifying other processes and structures for carrying out the same purposes and/or achieving the same advantages of the embodiments introduced herein. Those skilled in the art should also realize that such equivalent constructions do not depart from the spirit and scope of the present invention, and that they may make various changes, substitutions, and alterations herein without departing from the spirit and scope of the present invention. In addition, while a particular feature may have been disclosed with respect to only one of several embodiments, such feature may be combined with one or more other features of the other embodiments as may be desired or advantageous for a given application.

What is claimed is:

1. A plasma treatment system, comprising:
a process chamber;
a plasma source coupled to the process chamber, wherein the plasma source comprises a plasma chamber having one or more walls, and an aperture is formed through at least one of the walls;
a DC power source electrically connected between the walls and one or more first electrodes located outside the plasma chamber, wherein the one or more first electrodes are positioned to extract ions from the plasma chamber through the aperture and accelerate the extracted ions into the process chamber along a trajectory, and the trajectory corresponds to a line of sight from the plasma chamber to the process chamber through the aperture; and
a workpiece handler disposed within the process chamber, wherein the workpiece handler is operable to vary a distance of a workpiece from the plasma chamber.

2. The plasma treatment system of claim 1, wherein the one or more first electrodes are operable to form the ions into a beam, and the workpiece handler is operative to scan the workpiece through the beam.

3. The plasma treatment system of claim 2, wherein the one or more first electrodes are a set of extraction electrodes located between the workpiece handler and the plasma chamber.

4. The plasma treatment system of claim 3, further comprising a set of suppression electrodes between the set of extraction electrodes and the plasma chamber.

5. The plasma treatment system of claim 1, wherein the walls are isolated from ground and the DC power source is configured to raise the walls to a potential above ground.

6. The plasma treatment system of claim 1, further comprising an electronic control system configured to vary the distance.

7. The plasma treatment system of claim 1, further comprising a sensor in the process chamber, wherein the sensor has an output responsive to variations in neutral particle flux.

8. The plasma treatment system of claim 7, wherein the sensor is mounted to the workpiece handler.

9. The plasma treatment system of claim 1, wherein the workpiece handler is operable to scan the workpiece through a point along the trajectory while maintaining a planar surface of the workpiece in a plane having a normal vector that is tilted relative to the trajectory.

10. The plasma treatment system of claim 1, wherein the workpiece handler comprises a three-jointed robotic arm.

11. A method of operating a plasma treatment system, the method comprising:
receiving a workpiece in a process chamber that is in communication with a plasma chamber through an aperture;
generating a plasma within the plasma chamber;
extracting ions from the plasma chamber through the aperture using one or more extraction electrodes at a first distance from the plasma chamber to provide an ion beam, wherein the plasma chamber projects neutral particles from the plasma along the ion beam;
assessing a neutral particle-to-ion flux ratio in the ion beam at a second distance from the plasma chamber;
comparing the assessed neutral particle-to-ion flux ratio to a predefined target ratio;
determining a third distance from the plasma chamber, wherein the third distance is greater or less than the second distance according to whether the assessed neutral particle-to-ion flux ratio is above or below the predefined target ratio; and
treating a workpiece while holding the workpiece on a first process plane which is at the third distance from the plasma chamber along the ion beam, wherein the one or more extraction electrodes are maintained at the first distance from the plasma chamber.

12. The method of claim 11, wherein extracting ions from the plasma chamber through the aperture using one or more extraction electrodes comprises applying pulsed DC power between the plasma chamber and the one or more extraction electrodes.

13. The method of claim 12, wherein applying pulsed DC power between the plasma chamber and the one or more extraction electrodes comprises raising a potential of the plasma chamber above a ground potential while holding the one or more extraction electrodes at the ground potential.

14. The method of claim 13, wherein the pulsed DC power is applied according to a duty cycle having active periods and inactive periods, and the method further comprises:
applying a potential below ground to a set of suppression electrodes during the active periods; and
holding the set of suppression electrodes at or above ground during the inactive periods.

15. The method of claim 11, wherein treating the workpiece comprises scanning the workpiece through the ion beam while maintaining the workpiece in the first process plane, and the first process plane is tilted with respect to the ion beam.

16. The method of claim 11, wherein assessing the neutral particle-to-ion flux ratio in the ion beam at the second distance from the plasma chamber comprises taking a measurement.

17. The method of claim 11, further comprising, prior to removing the workpiece from the process chamber, applying a second treatment to the workpiece while holding the workpiece on a second process plane, wherein the second process plane is distinct from the first process plane.

18. A plasma treatment system, comprising:
a process chamber;
a plasma source mounted to the process chamber, wherein the plasma source comprises a plasma chamber having plasma chamber walls, and an aperture is formed through the plasma chamber walls;
a DC power source connected between the plasma chamber walls and one or more first electrodes outside the plasma chamber walls, wherein the one or more first electrodes are positioned to draw ions from the plasma chamber through the aperture and accelerate them along a trajectory into the process chamber, and the trajectory corresponds to a line of sight from the plasma chamber to the process chamber through the aperture; and
a workpiece handler mounted within the process chamber, wherein the workpiece handler is operable to scan a workpiece through a point along the trajectory while maintaining a planar surface of the workpiece in a plane having a normal vector that is tilted relative to the trajectory.

19. The plasma treatment system of claim 18, wherein the workpiece handler is operable to vary a distance of the point along the trajectory.

20. The plasma treatment system of claim 19, the one or more first electrodes are a set of extraction electrodes located between the workpiece handler and the plasma chamber.
